(19) United States
(12) Patent Application Publication
(10) Pub. No.: US 2023/0069464 A1
(43) Pub. Date: Mar. 2, 2023

(54) ELECTRO-OPTICAL DEVICE AND ELECTRONIC DEVICE

(71) Applicant: SEIKO EPSON CORPORATION, Tokyo (JP)

(72) Inventor: Hitoshi OTA, SHIOJIRI-SHI (JP)

(73) Assignee: SEIKO EPSON CORPORATION, Tokyo (JP)

(21) Appl. No.: 17/898,467

(22) Filed: Aug. 29, 2022

(30) Foreign Application Priority Data
Aug. 31, 2021 (JP) 2021-141521

(51) Int. Cl. H01L 27/32; G09G 3/3233

(52) U.S. Cl. CPC H01L 27/3279; G09G 3/3233; G09G 2300/0842; G09G 2320/0223; G09G 3/3266

(57) ABSTRACT

An electro-optical device is provided. The electro optical device includes: a light emitting element configured to emit light according to a current flowing between a pixel electrode and a common electrode; a plurality of power-supply wiring lines provided at a side of the pixel electrode and configured to be supplied with a power source potential; a plurality of data lines; a data-signal outputting circuit configured to output a data signal to a data line; a conductive wiring line provided to overlap with the data-signal outputting circuit in plan view and configured to be supplied with the power source potential through a plurality of mounting terminals, in which each of the plurality of power-supply wiring lines is provided between the plurality of data lines in plan view and electrically coupled to the conductive wiring line.

The present application is based on, and claims priority from JP Application Serial Number 2021-141521, filed on Aug. 31, 2021, the disclosure of which is hereby incorporated by reference herein in its entirety.

### BACKGROUND

### 1. Technical Field

The present disclosure relates to an electro-optical device and an electronic devices.

### 2. Related Art

For example, an electro-optical device using an OLED is known as a light emitting element driven by electric current. The OLED stands for an organic light emitting diode. This electro-optical device includes a pixel circuit provided so as to correspond to each pixel of a display image. The pixel circuit includes a transistor or the like configured to cause an electric current to flow through the light emitting element. The transistor supplies the light emitting element with an electric current according to the luminance level. With this configuration, the light emitting element emits light with luminance according to this electric current.

However, a technique described in JP-A-2017-142440 has a problem in that this technique is not able to sufficiently reduce the resistance of the wiring line used to supply the power source potential in the pixel circuit.

### SUMMARY

An electro-optical device according to one aspect of the present disclosure includes a light emitting element configured to emit light according to a current flowing between a pixel electrode and a common electrode, a plurality of power-supply wiring lines provided at a side of the pixel electrode and including a power-supply wiring line to which a power source potential is supplied, a plurality of data lines provided along a predetermined direction, a data-signal outputting circuit configured to output a data signal to one data line of the plurality of data lines, and a conductive wiring line provided so as to overlap with the data-signal outputting circuit in plan view and configured to be supplied with the power source potential through a plurality of mounting terminals, in which each of the plurality of power-supply wiring lines is provided between the plurality of data lines in plan view and is electrically coupled to the conductive wiring line.

### BRIEF DESCRIPTION OF THE DRAWINGS

FIG. 1 is a perspective view illustrating an electro-optical device according to an embodiment.

FIG. 2 is a block diagram illustrating an electrical configuration of the electro-optical device.

FIG. 3 is a circuit diagram illustrating a pixel circuit in the electro-optical device.

FIG. 4 is a diagram used to explain operation of the electro-optical device.

FIG. 5 is a plan view illustrating a layout of individual elements in the electro-optical device.

FIG. 6 is a plan view illustrating a conductive wiring line in the electro-optical device, the conductive wiring line being configured to supply a high-level potential from a power supply.

FIG. 7 is a plan view illustrating a conductive wiring line and a power-supply wiring line in the electro-optical device, the conductive wiring line and the power-supply wiring line being configured to supply a high-level potential from a power supply.

FIG. 8 is a plan view illustrating a common electrode in the electro-optical device.

FIG. 9 is a diagram illustrating a layout of a data-signal outputting circuit in the electro-optical device.

FIG. 10 is a diagram illustrating a layout of pixel circuits in the electro-optical device.

FIG. 11 is a plan view illustrating a wiring line structure at and around the data-signal outputting circuit.

FIG. 12 is a plan view illustrating a wiring line structure at and around the data-signal outputting circuit.

FIG. 13 is a partial cross-sectional view taken along the P-p line in FIG. 12.

FIG. 14 is a circuit diagram illustrating a pixel circuit in an electro-optical device according to a modification example.

FIG. 15 is a perspective view illustrating a head-mounted display using the electro-optical device.

FIG. 16 is a diagram illustrating an optical configuration of the head-mounted display.

### DESCRIPTION OF EXEMPLARY EMBODIMENTS

Below, an electro-optical device according to an embodiment of the present disclosure will be described with reference to the drawings. It should be noted that, in each of the drawings, the dimension and scale of each portion is set so as to appropriately differ from the actual dimension and scale of each corresponding portion. In addition, the embodiments described below are preferred specific examples, and various types of technically preferred limitation are applied. However, the scope of the present disclosure is not limited to these modes unless there is description that particularly limits the present disclosure.

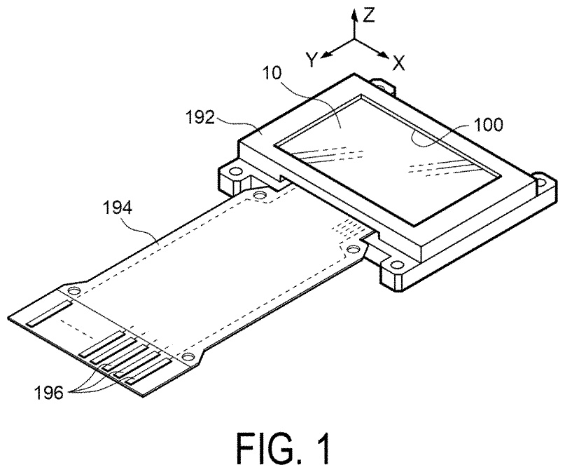

FIG. 1 is a perspective view illustrating the configuration of an electro-optical device according to an embodiment. An electro-optical device 10 is, for example, a micro display panel configured to display an image in a head-mounted display or the like. The electro-optical device 10 includes pixel circuits including a light emitting element, a driving circuit configured to drive the pixel circuits, or the like. The pixel circuits and the driving circuit are integrated at a semiconductor substrate. The semiconductor substrate is typically a silicon substrate but may be other semiconductor substrates.

The electro-optical device 10 is accommodated in a case 192 having a frame shape and opened at a display region 100. The electro-optical device 10 is coupled to one end of an FPC substrate 194. The FPC stands for a flexible printed circuit. A plurality of terminals 196 configured to be coupled to a host device, which is not illustrated, are provided at the other end of the FPC substrate 194. When the plurality of terminals 196 are coupled to the host device, the electro-optical device 10 is supplied with video data or a synchronization signal from the host device through the FPC substrate 194.

Note that, in the drawings, the X direction indicates a direction in which scanning lines in the electro-optical device 10 extend, and the Y direction indicates a direction in which data lines extend. The two-dimensional plane defined by the X direction and the Y direction is a substrate surface of the semiconductor substrate. The Z direction is perpendicular to the X direction and the Y direction, and indicates a direction in which light emitted from a light emitting element travels.

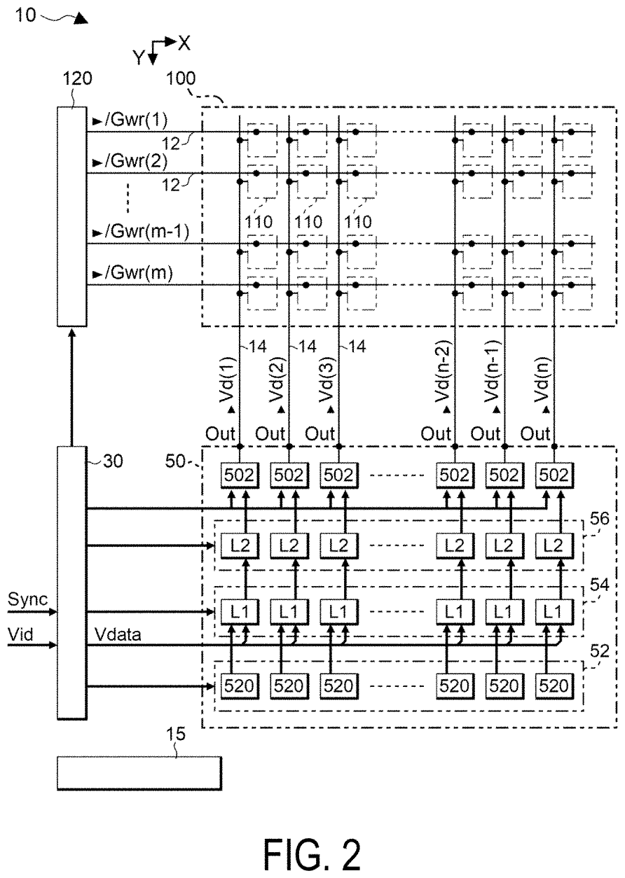

FIG. 2 is a block diagram illustrating the electrical configuration of the electro-optical device 10. As illustrated in the drawing, the electro-optical device 10 is generally divided into a power-supply circuit 15, a control circuit 30, a data-signal outputting circuit 50, a display region 100, and a scanning line drive circuit 120.

In the display region 100, m rows of scanning lines 12 are provided along the X direction in the drawing, and n columns of data lines 14 are provided along the Y direction so as to maintain electrical insulation from each of the scanning lines 12. Note that each of the “m” and the “n” is an integer equal to or more than 2.

In the display region 100, pixel circuits 110 are provided so as to correspond to intersections of m rows of scanning lines 12 and n columns of data lines 14. Thus, the pixel circuits 110 are arrayed in a matrix of m rows (vertical direction)×n columns (horizontal direction). In the matrix array, each row may be referred to as the first, second, third, . . . , (m−1)-th, or m-th row in the order from the top in the drawing, for the purpose of distinguishing individual rows. Similarly, each column may be referred to as the first, second, third, . . . , (n−1)-th, or n-th column in the order from the left in the drawing, for the purpose of distinguishing individual columns in the matrix.

Note that an integer i not less than 1 and not more than m is used in order to describe the scanning lines 12 in a generalized manner. Similarly, an integer j not less than 1 and not more than n is used in order to describe the data lines 14 in a generalized manner.

The control circuit 30 controls each component on the basis of the video data Vid or synchronization signal Sync supplied from the host device. The video data Vid designates a gray scale level of a pixel in an image to be displayed, for example, by 8 bits for each of three primary colors.

The synchronization signal Sync contains a vertical synchronization signal used to give an instruction to start vertical scanning of the video data Vid, a horizontal synchronization signal used to given an instruction to start horizontal scanning, and a dot clock signal indicating timing for one pixel of the video data.

In the present embodiment, a pixel of an image to be displayed corresponds, one by one, to the pixel circuit 110 in the display region 100.

The property of luminance of a gray scale level indicated by the video data Vid from the host device does not necessarily match the property of luminance at the OLED included in the pixel circuit 110. Thus, in the present embodiment, the control circuit 30 converts 8 bits of the video data Vid to increase, for example, to 10 bits, and outputs it as video data Vdata, in order to cause the OLED to emit light with luminance corresponding to the gray scale level indicated by the video data Vid. For this reason, the 10-bit video data Vdata is data corresponding to the gray scale level designated by the video data Vid.

Note that, in this up-conversion, a look-up table is used. The look-up table stores, in advance, a corresponding relationship between 8-bit video data Vid serving as input and 10-bit video data Vdata serving as output. In addition, the control circuit 30 generates various types of control signal used to control each component.

The scanning line drive circuit 120 is a circuit configured to output various types of signals to drive, one row by one row, the pixel circuits 110 arrayed in m rows and n columns in accordance with control by the control circuit 30. For example, the scanning line drive circuit 120 sequentially supplies the scanning lines 12 in the first, second, third, . . . , (m−1)-th, and m-th rows with scanning signals /Gwr(1), /Gwr(2), . . . , /Gwr(m−1), and /Gwr(m). In general, the /Gwr(i) represents a scanning signal supplied to a scanning line 12 in the i-th row.

The data-signal outputting circuit 50 is a circuit configured to output a data signal of a potential corresponding to the luminance from a node Out toward pixel circuits 110 in a row selected by the scanning line drive circuit 120. Specifically, the data-signal outputting circuit 50 includes a selection circuit group 52, a first latching circuit group 54, a second latching circuit group 56, and n pieces of DA conversion circuits 502. The selection circuit group 52 includes a selection circuit 520 corresponding to each of n pieces of columns. The first latching circuit group 54 includes a first latching circuit L1 corresponding to each of n pieces of columns. The second latching circuit group 56 includes a second latching circuit L2 corresponding to each of n piece of columns.

That is, a set of the selection circuit 520, the first latching circuit L1, the second latching circuit L2, and the DA conversion circuit 502 is provided in correspondence with each example. The selection circuit 520 in the j-th column provides the first latching circuit L1 in the j-th column with an instruction as to selection of video data on the j-th column from the video data Vdata outputted from the control circuit 30. The first latching circuit L1 in the j-th column latches the video data Vdata as per this instruction. The second latching circuit L2 in the j-th column outputs the video data Vdata latches by the first latching circuit L1 in the j-th column, to the DA conversion circuit 502 in the j-th column in accordance with control by the control circuit 30.

The DA conversion circuit 502 in the j-th column converts the 10-bit video data Vdata outputted from the second latching circuit L2 in the j-th column into an analog data signal, and outputs it to the data line 14 in the j-th column as a data signal.

In the drawing, potentials of the data lines 14 in the first, second, . . . , (n−1)-th, and n-th columns are sequentially referred to as Vd(1), Vd(2), . . . , Vd(n−1), and Vd(n). In general, the potential of the data line 14 in the j-th column is referred to as Vd(j).

Note that the power-supply circuit 15 generates a power supply voltage or potential for the control circuit 30, the scanning line drive circuit 120, and the data-signal outputting circuit 50. The reference of voltage zero is the ground potential Gnd. However, in other points, the potential and the voltage are not exactly separately used in the present description. In the present description, the power source potential represents a substantially temporally constant potential.

Furthermore, potentials Vel and Vct that will be described later, that is, a high-level potential and a low-level potential of a power supply at the light emitting element that will be described later are supplied from an external host device through the FPC substrate 194, rather than from the power-supply circuit 15.

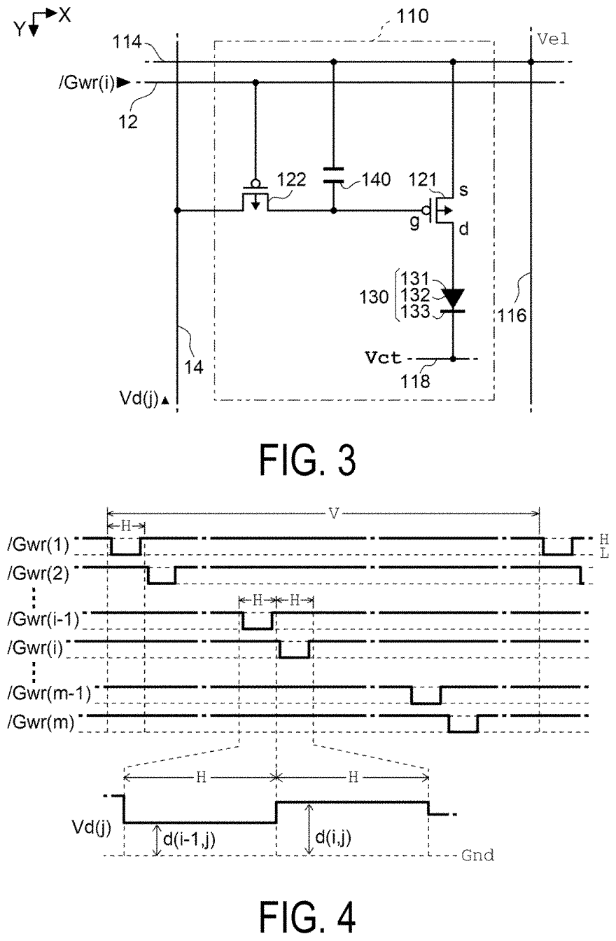

FIG. 3 is a circuit diagram illustrating a pixel circuit 110. The pixel circuits 110 arrayed in the m rows and n columns are electrically identical to each other. Thus, the pixel circuit 110 will be described by using a pixel circuit 110 disposed at the i-th row and j-th column as a representative pixel circuit.

As illustrated in the drawing, the pixel circuit 110 includes an OLED 130, p-channel type transistors 121 and 122, and a capacitance element 140. The transistor 121, 122 is, for example, a MOS. Note that the MOS stands for a metal-oxide-semiconductor field-effect transistor.

The OLED 130 is a light emitting element in which a light emission function layer 132 is interposed between a pixel electrode 131 and a common electrode 133. The pixel electrode 131 functions as anode, and the common electrode 133 functions as cathode. Note that the common electrode 133 has a light reflective property and optical transparency, and hence, serves as one example of a semi-reflective and semi-transparent reflection layer. In the OLED 130, once an electric current flows from the anode toward the cathode, a positive hole injected from the anode and an electron injected from the cathode are re-bonded at the light emission function layer 132 to generate exciton, whereby white light is generated.

When color display is performed, the generated white light resonates at an optical resonator, for example, formed of a reflection layer that is not illustrated and a semi-reflective and semi-transparent layer. Then, light having a resonance wavelength set so as to correspond to any of colors of R(red), G(green), and B(blue) is outputted. A color filter corresponding to the color is provided at the side where light is outputted from the optical resonator. With this configuration, the light outputted from the OLED 130 is colored through the optical resonator and the color filter, and is visually recognized by an observer. Note that the optical resonator is not illustrated in the drawing. In addition, when the electro-optical device 10 simply displays a single color image representing only light and darkness, the color filter described above is not provided.

At a transistor 121 of a pixel circuit 110 at the i-th row and j-th column, the gate node g is coupled to the drain node of the transistor 122, the source node s is coupled to a power-supply wiring line 114 to which a potential Vel is supplied, and the drain node d is coupled to the pixel electrode 131 serving as the anode of the OLED 130.

The power-supply wiring line 114 is formed along the X direction in the drawing. This power-supply wiring line 114 is electrically coupled to a power-supply wiring line 116 formed along the Y direction in the drawing.

In this description, the expression “electrically couple” or simply “couple” means direct or indirect coupling or connection of two or more elements, and includes, for example, coupling between two or more elements at a semiconductor substrate through a different wiring layer or contact hole even though the coupling is not made directly.

The common electrode 133 functioning as the cathode of the OLED 130 is supplied with a potential Vct through a power-supply wiring line 118. Note that the anode of the OLED 130 is an electrode provided individually for each of the pixel circuits 110 whereas the cathode of the OLED 130 is an electrode common to all the pixel circuits 110. Thus, the common electrode 133 can be considered to be the power-supply wiring line 118.

At a transistor 122 of a pixel circuit 110 at the i-th row and j-th column, the gate node is coupled to the scanning line 12 in the i-th row, and the source node s is coupled to the data line 14 in the j-th column. The capacitance element 140 has one end coupled to the gate node g of the transistor 121 and the other end coupled to the power-supply wiring line 116. Thus, the capacitance element 140 holds a voltage across the gate node g and the source node s of the transistor 121. Note that it is only necessary that the potential of the other end of the capacitance element 140 is kept substantially constant, and hence, the other end of the capacitance element 140 may be coupled to other power-supply wiring lines configured to supply potential other than the potential Vel.

A so-called MOS capacitor is used for the capacitance element 140. The MOS capacitor is formed by interposing a gate insulation layer of the transistor between a semiconductor layer of the transistor and a gate electrode. Note that, for the capacitance element 140, it may be possible to use a parasitic capacitor of the gate node g of the transistor 121 or use a so-called metal capacitor formed by interposing an insulating layer between conductive layers differing from each other in the semiconductor substrate.

FIG. 4 is a timing chart used to explain operation of the electro-optical device 10.

In the electro-optical device 10, m rows of scanning lines 12 are scanned one row by one row in a period of frame (V) in the order of the first, second, third, . . . , and m-th rows. Specifically, as illustrated in the drawing, the scanning line drive circuit 120 sequentially brings the scanning signals /Gwr(1), /Gwr(2), . . . , /Gwr(m−1), and /Gwr(m) into an L level in an exclusive manner for every horizontal scanning period (H).

Note that, in the present embodiment, periods in which adjacent scanning signals of the scanning signals /Gwr(1) to /Gwr(m) are brought into the L level are temporally separated from each other. Specifically, after the scanning signal /Gwr(i−1) changes from the L level into the H level and a certain period elapses, the next scanning signal/Gwr(i) changes into the L level. This certain period corresponds to a horizontal blanking interval.

The period of one frame (V) as used here represents a period required to display one frame of an image designated by the video data Vid. When the length of a period of one frame (V) is equal to a vertical synchronization period and the frequency of the vertical synchronization signal contained in the synchronization signal Sync is, for example, 60 Hz, the length of a period of one frame (V) is 16.7 milliseconds corresponding to one cycle of this vertical synchronization signal. In addition, the horizontal scanning period (H) represents a time interval at which the scanning signals /Gwr(1) to /Gwr(m) are sequentially changed into the L level. In the drawing, the timing at which the horizontal scanning period (H) starts is set to almost the center of the horizontal blanking interval, for the purpose of convenience.

When a certain scanning signal of the scanning signals /Gwr(1) to /Gwr(m), that is, for example, a scanning signal /Gwr(i) to be supplied to a scanning line 12 in the i-th row is changed into the L level, the transistor 122 of a pixel circuit 110 at the i-th row and j-th column is brought into the ON state in a case of the j-th column. Thus, the gate node g of the transistor 121 of this pixel circuit 110 is electrically coupled to the data line 14 in the j-th column.

Note that, in the present description, the “ON state” of a transistor represents a state in which the source node and the drain node of the transistor are electrically closed to be in a low impedance state. Furthermore, the “OFF state” of a transistor represents a state in which the source node and the drain node are electrically opened to be in a high impedance state.

During the horizontal scanning period (H) in which the scanning signal/Gwr(i) is at the L level, the data-signal outputting circuit 50 convers gray scale levels of pixels at the i-th row and first column to the i-th row and n-th column indicated by the video data Vdata, into analog potentials Vd(1) to Vd(n), and outputs them to the data lines 14 in the first to n-th columns as data signals. In a case of the j-th column, the data-signal outputting circuit 50 converts a gray scale level d(i,j) of a pixel at the i-th row and j-th column into a potential Vd(j) that is an analog signal, and outputs it to the data line 14 in the j-th column as a data signal.

Note that, during the horizontal scanning period (H) in which a scanning signal/Gwr(i−1) in a row that is one row preceding the scanning signal/Gwr(i) is changed into the L level, the data-signal outputting circuit 50 converts a gray scale level d(i−1,j) of a pixel at the (i−1)-th row and the j-th column into a potential Vd(j) that is an analog signal, and outputs it to the data line 14 in the j-th column as a data signal.

The data signal of this potential Vd(j) is applied, through the data line 14 in the j-th column, to the gate node g of the transistor 121 of the pixel circuit 110 at the i-th row and j-th column, and this potential Vd(j) is held by the capacitance element 140. Thus, this transistor 121 causes a current corresponding to a voltage across the gate node and the source node to flow into the OLED 130.

Even when the scanning signal Gwr(i) is changed into the H level and the transistor 122 is brought into the OFF state, the potential Vd(j) is held by the capacitance element 140, and hence, the current is kept flowing into the OLED 130. Thus, in the pixel circuit 110 at the i-th row and j-th column, the OLED 130 keeps emitting light with brightness according to the voltage held by the capacitance element 140, that is, according to the gray scale level, until the period of one frame (V) elapses and the transistor 122 is brought into the ON again to apply a voltage of the data signal again.

Note that the pixel circuit 110 at the i-th row and j-th column has been described here. In addition, in pixel circuits 110 at the i-th row and columns other than the j-th column, the OLED 130 also emits light with luminance indicated by the video data Vdata.

Furthermore, as the scanning signals /Gwr(1) to /Gwr(m) are sequentially changed into the L level, the OLEDs 130 of pixel circuits 110 in rows other than the i-th row also emit light with luminance indicated by the video data Vdata.

Thus, in the electro-optical device 10, during the period of one frame (V), OLEDs 130 of all the pixel circuits 110 from the pixel circuit 110 at the first row and first column to the pixel circuit 110 at the m-th row and n-th column emit light with luminance indicated by the video data Vdata, and an image of one frame is displayed.

As described above, in the pixel circuit 110, the OLED 130 is disposed between the power-supply wiring line 116 having the potential Vel at the high-level power source and the power-supply wiring line 118 having the potential Vct at the low-level power source, and is configured such that the current flowing through this OLED 130 is controlled by the transistor 121. In such a configuration, when the resistance of a wiring line used to supply the potential Vel is high, the potential Vel, which should be constant, is unstable due to a voltage drop, which causes a deterioration in the display quality. In the present embodiment, the potential Vel is supplied from the external host device through the mounting terminal 20 as described above. Thus, in the present embodiment, description will be made below of a configuration in which the potential Vel is supplied from the plurality of mounting terminals 20 to the pixel circuit 110.

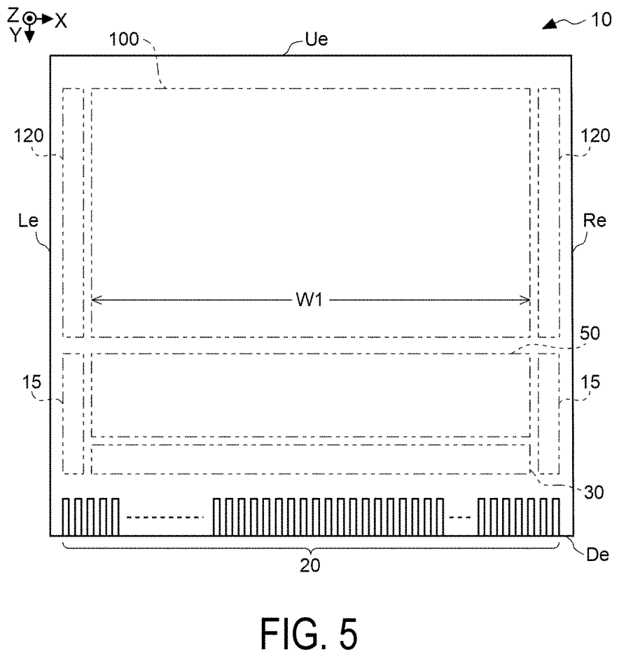

FIG. 5 is a plan view illustrating a layout of each component in the electro-optical device 10. The electro-optical device 10 is diced from a wafer-shaped semiconductor substrate, and hence, has a rectangular shape. Thus, of the electro-optical device 10 having the rectangular shape, the upper side is denoted by the reference “Ue”, the lower side is denoted by the reference “De”, the left-hand side is denoted by the reference “Le”, and the right-hand side is denoted by the reference “Re”.

Note that, in the electro-optical device 10 having the rectangular shape, the upper side Ue and the lower side De extend along the X direction in which the scanning line 12 extends, and the left-hand side Le and the right-hand side Re extend along the Y direction in which the data line 14 extends. Furthermore, in the present description, the expression “plan view” indicates a case in which the electro-optical device 10 is viewed from a direction opposite to the Z direction.

The scanning line drive circuit 120 is provided in a region between the display region 100 and the left-hand side Le. The scanning line drive circuit 120 is provided in a region between the display region 100 and the right-hand side Re. The two scanning line drive circuits 120 have the same configuration, and drive the scanning line 12 or the like at the left and the right. With a configuration in which only one scanning line drive circuit 120 is disposed at either the left or right, a signal delay occurs at the other side of the left and the right. In contrast, with the configuration in which the scanning line drive circuit 120 is disposed at both sides of the left and the right, it is possible to prevent the signal delay from occurring.

In the electro-optical device 10, the plurality of mounting terminals 20 used to be coupled to one end of the FPC substrate 194 are provided along the lower side De. In a region between the display region 100 and the plurality of mounting terminals 20, the data-signal outputting circuit 50 and the control circuit 30 are provided in the order as viewed from the display region 100. Note that the W1 represents the length (width) of the display region 100 along the X direction.

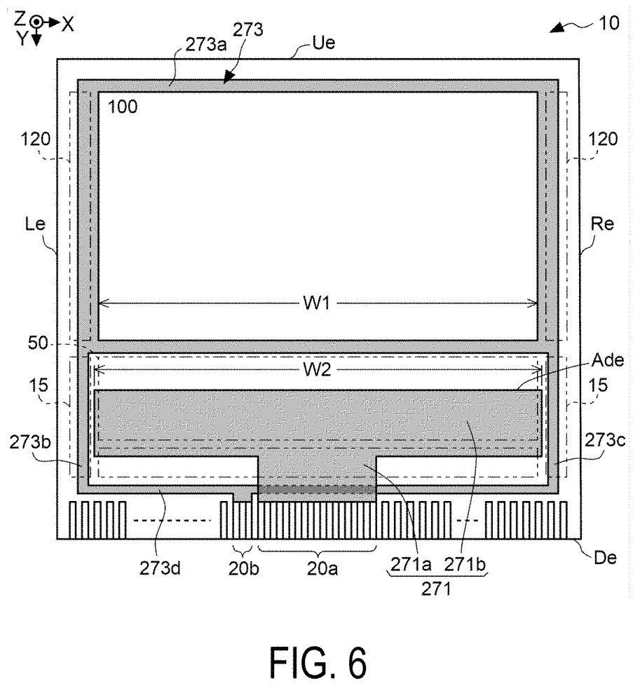

FIG. 6 is a diagram schematically illustrating a conductive wiring line of each component of the electro-optical device 10. The conductive wiring line is to be coupled to the mounting terminal 20 and is used to supply the potentials Vel and Vct from the power source to or around the display region 100.

Note that, in the present description, the “line” of the data line or the scanning line means a supply path for a signal. In addition, the “wiring line” of the power-supply wiring line or the conductive wiring line means one element of a signal path formed through patterning of a wiring layer at a semiconductor substrate. That is, the supply path formed of the “line” described above is formed by coupling a plurality of wiring lines through a contact hole or the like.

A conductive wiring line 271 is part of a signal path used to supply the potential Vel from the power source to the pixel circuit 110, and has a letter-T shape in plan view. Specifically, the conductive wiring line 271 includes a base portion 271a to be coupled to a plurality of mounting terminals 20a, disposed at or around the center, of the mounting terminal 20 arrayed along the X direction, and an expansion portion 271b extending from the base portion 271a toward the display region 100. Part of the conductive wiring line 271 overlaps with part of the data-signal outputting circuit 50 in plan view. Of the conductive wiring line 271, the W2 represents the length (width) along the X direction of the expansion portion 271b. The width W2 includes the width W1 as illustrated in the drawing, and is equal to or more than the width W1.

Note that, the “Ade” represents the upper side of the expansion portion 271b of the conductive wiring line 271, that is, the side that is opposed to the display region 100.

A conductive wiring line 273 is part of a signal path used to supply the potential Vct from the power source to the pixel circuit 110, and includes a frame portion 273a, an extension portions 273b and 273c, and a connecting portion 273d, each of which surrounds the display region 100 in plan view. The conductive wiring line 273 is formed of a wiring layer differing from the layer of the conductive wiring line 271. The extension portion 273b extends along the Y direction from the left lower end of the frame portion 273a. The extension portion 273c extends along the Y direction from the right lower end of the frame portion 273a. The connecting portion 273d couples the extension portions 273b and 273c, and is also coupled to the plurality of mounting terminals 20b disposed to the left of the plurality of mounting terminals 20a. Note that part of the connecting portion 273d passes through the lower layer of the base portion 271a. In addition, of the conductive wiring line 273, part of the frame portion 273a may overlap with part of the scanning line drive circuit 120 in plan view.

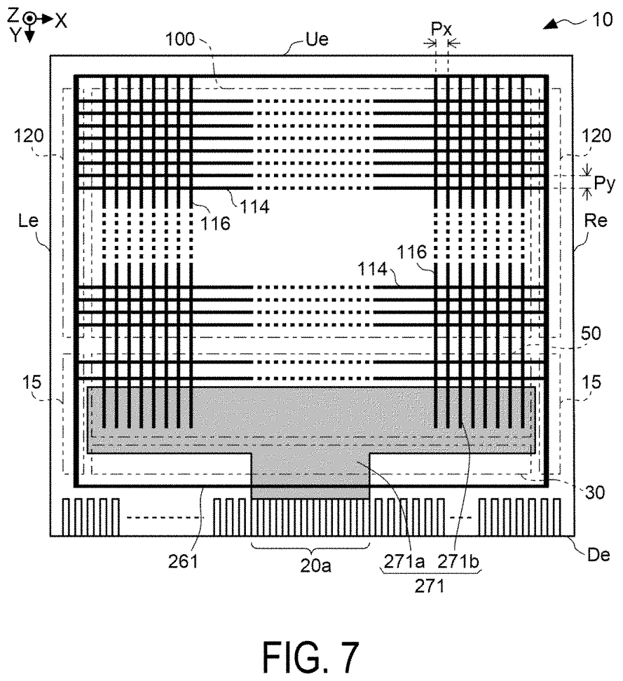

FIG. 7 is a diagram schematically illustrating the power-supply wiring lines 114, 116, and 261 of each component of the electro-optical device 10. Through the power-supply wiring lines 114, 116, and 261, the potential Vel from the power source is supplied from the conductive wiring line 271 to the display region 100. In the drawing, the power-supply wiring lines 116 and 261 are formed through patterning at a wiring layer disposed at a lower layer than the uppermost layer of wiring layers at the semiconductor substrate that constitutes the electro-optical device 10.

The power-supply wiring line 261 has a frame shape that surrounds the display region 100 in plan view. Of this frame shape, part of the side along the lower side De overlaps with the base portion 271a of the conductive wiring line 271 in plan view. The power-supply wiring line 261 and the conductive wiring line 271 are electrically coupled to each other through a plurality of contact hole (not illustrated) provided in this overlapping region.

In the present embodiment, in the display region 100, pixel circuits 110 are provided at an interval of a pitch Px in the X direction and are provided at an interval of pitch Py in the Y direction. Thus, the power-supply wiring lines 114 are also provided at an interval of the pitch Py, and the power-supply wiring lines 116 are also provided at an interval of the pitch Px. In addition, the power-supply wiring lines 114 and 116 are provided so as to surround part of the pixel circuit 110 in the display region 100 in plan view. Note that, although detailed description will not be given, the power-supply wiring lines 114 and 116 are electrically coupled to each other through a contact hole.

The power-supply wiring lines 116 are extended to the lower portion of the display region 100 in the drawing so as to overlap with part of the conductive wiring line 271 in plan view.

The power-supply wiring lines 114 are extended toward a direction opposite to the X direction up to a portion of the power-supply wiring line 261 that is along the left-hand side Le, and are also extended toward the X direction up to a portion of the power-supply wiring line 261 that is along the right-hand side Re. Thus, both the left and right ends of the power-supply wiring line 114 overlap with the power-supply wiring line 261 in plan view, and at this overlapping portion, the power-supply wiring line 261 and the power-supply wiring lines 114 are electrically coupled to each other through contact holes.

The power-supply wiring lines 116 are extended toward the Y direction up to a portion of the power-supply wiring line 261 that is along the upper side Ue. Thus, the upper end of the power-supply wiring line 116 overlaps with the power-supply wiring line 261 in plan view, and at this overlapping portion, the power-supply wiring line 261 and the power-supply wiring lines 116 are electrically coupled to each other through contact holes.

Note that, in a region where the power-supply wiring lines 116 overlap with part of the expansion portion 271b of the conductive wiring line 271 in plan view, the power-supply wiring lines 116 and the expansion portion 271b are electrically coupled to each other through contact holes, as described later.

In this manner, in the present embodiment, the potential Vel supplied from the external host device through the plurality of mounting terminals 20a is supplied to the power-supply wiring line 261 through the base portion 271a of the conductive wiring line 271, and is supplied to the power-supply wiring line 116 through the expansion portion 271b.

Unlike the other wiring lines, the conductive wiring line 271 has the expanded width, and the wiring line resistance thereof is small. Through this conductive wiring line 271, the potential Vel is supplied to the power-supply wiring line 114 extending along the X direction and the power-supply wiring line 116 extending along the Y direction, and is supplied through the power-supply wiring lines 114 and 116 in a mesh manner in plan view in the display region 100. Thus, with the present embodiment, the wiring line resistance is reduced in the supply path for the potential Vel from the mounting terminal 20a and the display region 100. This makes it possible to suppress a reduction in the display quality resulting from a voltage drop and non-uniformity in voltage.

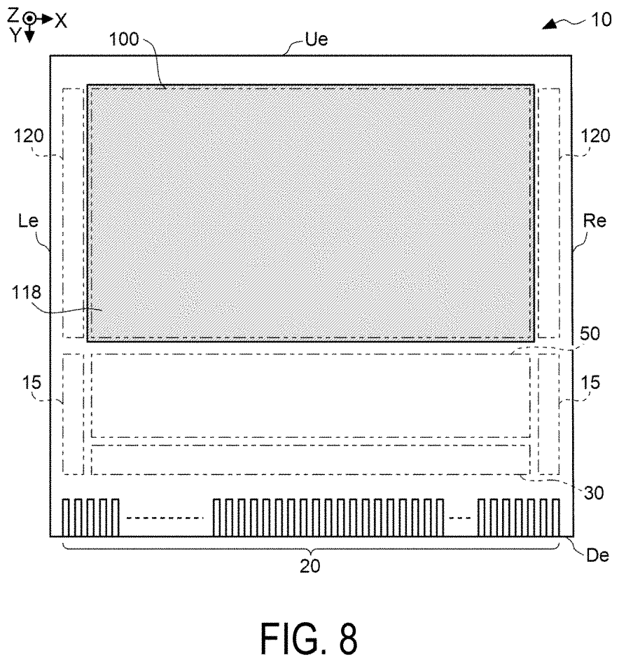

FIG. 8 is a plan view schematically illustrating the common electrode 133 (power-supply wiring line 118) of each component of the electro-optical device 10. The common electrode 133 (power-supply wiring line 118) is used to supply the potential Vct from the power source. In the drawing, the common electrode 133 is obtained by performing patterning of a transparent conductive layer provided at the upper layer of the wiring layer that constitutes the conductive wiring line 271, 273, and is provided so as to cover the display region 100 in plan view. Furthermore, the common electrode 133 may be a conductive layer having a semi-reflective and semi-transparent property. Note that the common electrode 133 is electrically coupled at a portion that overlaps with the frame portion 273a of the conductive wiring line 273 in plan view. With this configuration, the common electrode 133 is supplied with the potential Vct through the plurality of mounting terminals 20b and the conductive wiring line 273.

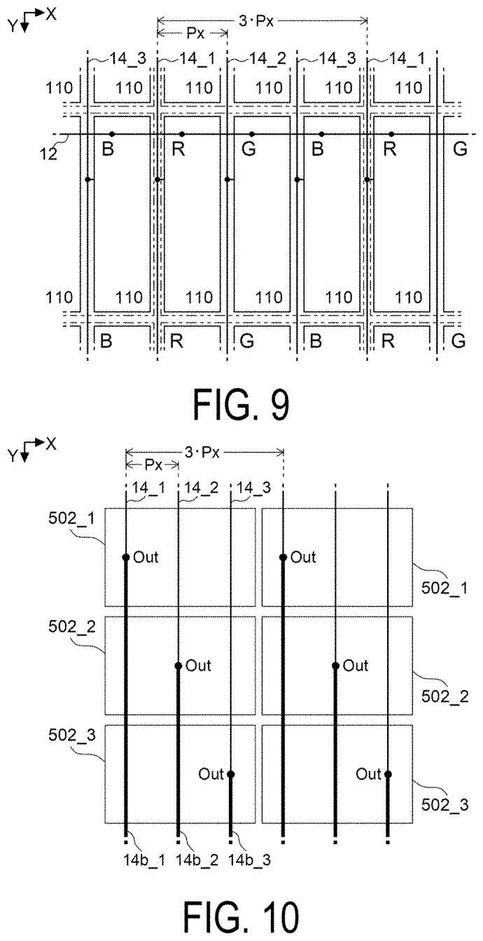

FIG. 9 is a plan view illustrating a layout of pixel circuits 110 in the display region 100. As illustrated in the drawing, a pixel circuit 110 for R, a pixel circuit 110 for B, and a pixel circuit 110 for G are arrayed along the X direction, and the pixel circuits 110 for the same color are arrayed along the Y direction. Thus, when focus is placed on a data line 14 in a certain column, this data line 14 corresponds to a pixel circuit 110 for the same color.

Note that one color is represented by additive color mixing of RGB pixel circuits 110 adjacent to each other in the X direction. Thus, the pixel circuit 110 should be called a sub pixel circuit in the strict sense. However, in the present embodiment, it is possible to display a single-color image representing only light and darkness as described above. Thus, for this reason, the pixel circuit 110 is referred to as a pixel circuit without making distinction between them.

As described above, in the display region 100, pixel circuits 110 are provided at an interval of the pitch Px in the X direction. Hence, the data lines 14 are also provided at an interval of the pitch Px. Note that, in the drawing, the pitch “3·Py” represents an interval three times greater than the pitch Py, that is, an interval obtained by setting, as one unit, three data lines 14 required to display one color.

In addition, in the drawing, in order to distinguish data lines 14 for each color, a data line corresponding to a pixel circuit 110 for R is denoted with the character “14_1”, a data line corresponding to a pixel circuit 110 for G is denoted with the character “14_2”, and a data line corresponding to a pixel circuit 110 for B is denoted with the character “14_3”. When no color separation is made, data lines are denoted with the character “14” as described above.

FIG. 10 is a diagram illustrating a layout of each component of DA conversion circuits 502 for six adjacent columns, of the data-signal outputting circuit 50.

In the drawing, in order to distinguish DA conversion circuits 502 for each color, a DA conversion circuit configured to output a data signal from a node Out toward the data line 14_1 for R is denoted with the character 502_1, as with the data line 14. Similarly, a DA conversion circuit configured to output a data signal from a node Out toward the data line 14_2 for G is denoted with the character 502_2, and a DA conversion circuit configured to output a data signal from a node Out toward the data line 14_3 for B is denoted with the character 502_3.

As illustrated in the drawing, the DA conversion circuits 502_1, 502_2, and 502_3 are arrayed in one line along the Y direction in a range wider than the pitch Px and narrower than the pitch 3·Px.

The node Out of the DA conversion circuit 502_1 is coupled to a relay line 14b_1 for R directed in the Y direction, separately from the data line 14_1 for R directed in a direction opposite to the Y direction. Similarly, the node Out of the DA conversion circuit 502_2 is coupled to a relay line 14b_2 for G directed in the Y direction, separately from the data line 14_2 for G. The node Out of the DA conversion circuit 502_3 is coupled to a relay line 14b_3 for B directed in the Y direction, separately from the data line 14_1 for B.

When various types of elements, the wiring lines, and the like are arrayed at the semiconductor substrate, it is efficient to divide a certain area into blocks, and repeat this separation into blocks to arrange them. In addition, as for the relay lines 14b_1, 14b_1, and 14b_3, it is preferable to employ a configuration in which these lines are coupled to an inspection circuit (not illustrated) separately provided at the electro-optical device 10 so as to be able to carry out inspection as to whether or not any failure in the manufacturing process exists.

Thus, although the relay lines 14b_1, 14b_2 and 14b_3 are redundant, the relay lines extend in the Y direction as indicated by the thick lines in FIG. 10, and are coupled to the inspection circuit provided, for example, at a lower portion in the drawing. Note that the term “redundant” as used herein means that the relay lines 14b_1, 14b_2, and 14b_3 indicated by the thick lines are not necessary from the viewpoint of transmitting data signals to the display region 100.

In such a configuration, for example, in a region of the data-signal outputting circuit 50 where the DA conversion circuit 502_1 is provided, the relay lines 14b_1 and 14b_2 are provided in place of the data line 14_1 for R and the data line 14_2 for G.

In this manner, in a region where the data-signal outputting circuit 50 is provided, the data line 14 or the relay line 14b is provided along the Y direction. Thus, in the following description, in a region where the data-signal outputting circuit 50 is provided, no particular distinction is made between the data line 14 and the relay line 14b, and these lines are described as the former data line 14.

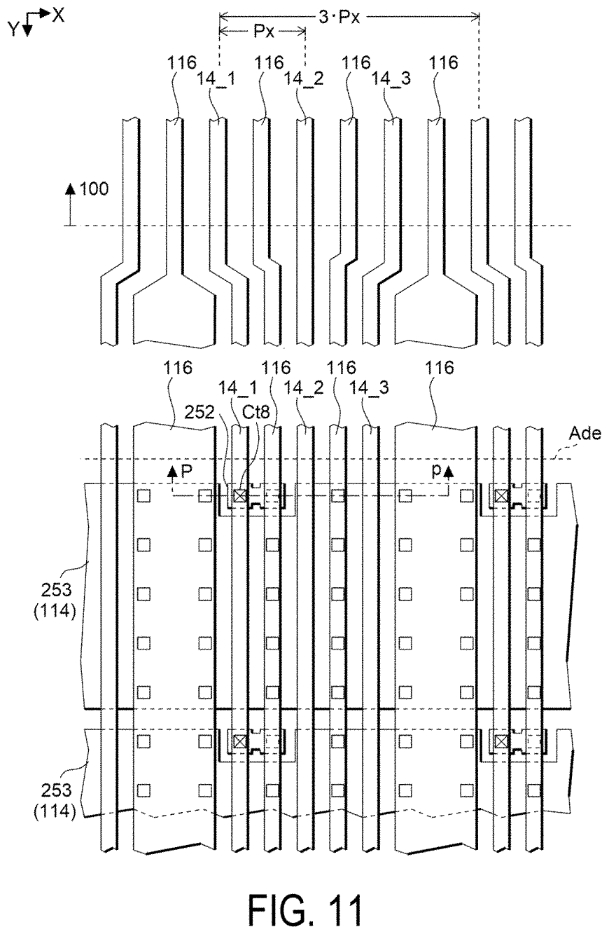

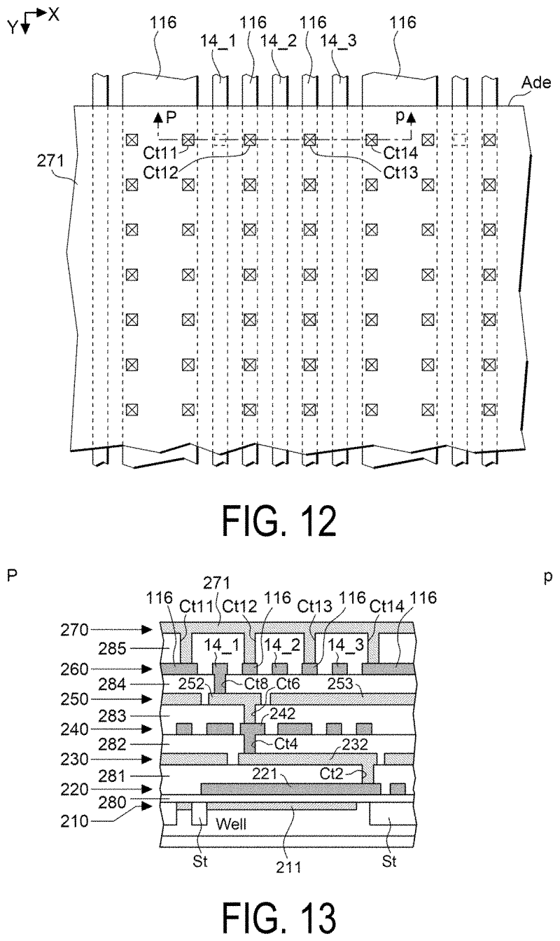

FIGS. 11 to 13 are diagrams used to explain specific structure of wiring lines of the conductive wiring line 271, the power-supply wiring line 116, and the data line 14 in a region including the side Ade of the conductive wiring line 271. Specifically, FIGS. 11 and 12 are plan views illustrating the configuration of the data lines 14_1, 14_2, and 14_3, the power-supply wiring line 116, and the conductive wiring line 271. FIG. 13 is a partial cross-sectional view taken along the line P-p in FIG. 12.

The electro-optical device 10 is formed at the semiconductor substrate as described above. At this semiconductor substrate, layers used as the conductive layer or the wiring layer include seven layers of a semiconductor layer 210, a gate electrode layer 220, a first wiring layer 230, a second wiring layer 240, a third wiring layer 250, a fourth wiring layer 260, and a fifth wiring layer 270 in the order from the base member as illustrated in FIG. 13. Thus, if the structure of the wiring lines were illustrated in plan view in one diagram, this diagram would become complicated and difficult to view. For this reason, FIG. 11 only illustrates the wiring line patterns of the third wiring layer 250 and the fourth wiring layer 260 from among the seven layers of the wiring layers described above, and FIG. 12 only illustrates the wiring line patterns of the fourth wiring layer 260 and the fifth wiring layer 270.

As illustrated in FIG. 13, the capacitance element that constitutes the DA conversion circuit 502 is formed by interposing the gate insulation layer 280 between an electrode 211 formed of the semiconductor layer 210 and an electrode 221 obtained by performing patterning of the gate electrode layer 220. Note that the electrode 211 is formed, for example, by injecting impurity ions into a p-well region Well. TA region St is a trench used to separate regions of adjacent elements.

The electrode 221 is coupled to a wiring line 232 through a contact hole Ct2 opened in a first interlayer insulating layer 281. The first interlayer insulating layer 281 is an insulating layer provided between the gate electrode layer 220 and the first wiring layer 230. A wiring line 231 is a wiring line formed through patterning of the first wiring layer 230.

Note that, for example, through a contact hole opened in the gate insulation layer 280 and the first interlayer insulating layer 281, the electrode 211 is coupled to a wiring line formed by performing patterning of the first wiring layer 230, although no particular illustration is given.

The wiring line 232 is coupled to a wiring line 242 through a contact hole Ct4 opened in a second interlayer insulating layer 282. The second interlayer insulating layer 282 is an insulating layer provided between the first wiring layer 230 and the second wiring layer 240. The wiring line 242 is a relaying wiring line formed by performing patterning of the second wiring layer 240.

The wiring line 242 is coupled to a wiring line 252 through a contact hole Ct6 opened in a third interlayer insulating layer 283. The third interlayer insulating layer 283 is an insulating layer provided between the second wiring layer 240 and the third wiring layer 250. A wiring line 253 is a relay wiring line formed by performing patterning of the third wiring layer 250, and is the power-supply wiring line 114 used to supply the potential Vel. That is, although the wiring line 253 and the power-supply wiring line 114 have been described separately for the purpose of convenience of explanation, these are actually the same element.

As illustrated in FIGS. 11 and 13, the wiring line 252 is coupled to the data line 14_1 through a contact hole Ct8 opened in a fourth interlayer insulating layer 284. The fourth interlayer insulating layer 284 is an insulating layer provided between the third wiring layer 250 and the fourth wiring layer 260. The data line 14_1 is formed by performing patterning of the fourth wiring layer 260. In addition to the data line 14_1, the data lines 14_2 and 14_3 and the power-supply wiring line 116 are formed by performing patterning of the fourth wiring layer 260. Note that the power-supply wiring line 116 is provided between the data lines 14_1 and 14_2, between the data lines 14_2 and 14_3, and between the data lines 14_3 and 14_1.

Of the power-supply wiring lines 116, the width of the power-supply wiring line 116 provided between the data lines 14_3 and 14_1, that is, the width that is the length thereof in the X direction is wider than the widths of the other power-supply wiring lines 116 due to the configuration of the circuit. Thus, in a region where the data-signal outputting circuit 50 is provided in plan view, the pitches in the X direction at which the data lines 14_1, 14_2, and 14_3 and the power-supply wiring line 116 are provided are not evenly spaced, whereas, in the display region 100 at the upper portion of the drawing, these pitches (Px) are changed to be evenly spaced.

As illustrated in FIGS. 12 and 13, the plurality of power-supply wiring lines 116 are coupled to the conductive wiring line 271 through a plurality of contact holes opened in a fifth interlayer insulating layer 285, for example, through contact holes Ct11, Ct12, Ct13, and Ct14. The fifth interlayer insulating layer 285 is an insulating layer provided between the fourth wiring layer 260 and the fifth wiring layer 270. The conductive wiring line 271 is formed by performing patterning of the fifth wiring layer 270 as described above.

Note that, in addition to the conductive wiring line 271, a reflection layer provided at a lower layer of the pixel electrode 131 is formed in the display region 100 through patterning of the fifth wiring layer 270.

In addition, in FIG. 13, layers disposed higher than the conductive wiring line 271 are not illustrated. However, in reality, the light emission function layer 132, the common electrode 113 (power-supply wiring line 118), an encapsulating layer, and the like that constitute the OLED 130 of the display region 100 are provided.

### Application Examples⋅Modification Example

In the embodiment described above, various modifications or applications are possible in the following manner.

In the display region 100, the power-supply wiring lines 114 and 116 used to supply the potential Vel at the high-level power source may be configured as a multiple layer. For example, in the display region 100, configuration may be made such that: a power-supply wiring line along the X direction is formed by performing patterning of the first wiring layer 230; a mesh-shaped power-supply wiring line is formed along the X direction and the Y direction by performing patterning of the second wiring layer 240; a power-supply wiring line along the Y direction is formed by performing patterning of the third wiring layer 250; a mesh-shaped power-supply wiring line is formed along the X direction and the Y direction by performing patterning of the fourth wiring layer 260; and these power-supply wiring lines are electrically coupled to each other through contact holes.

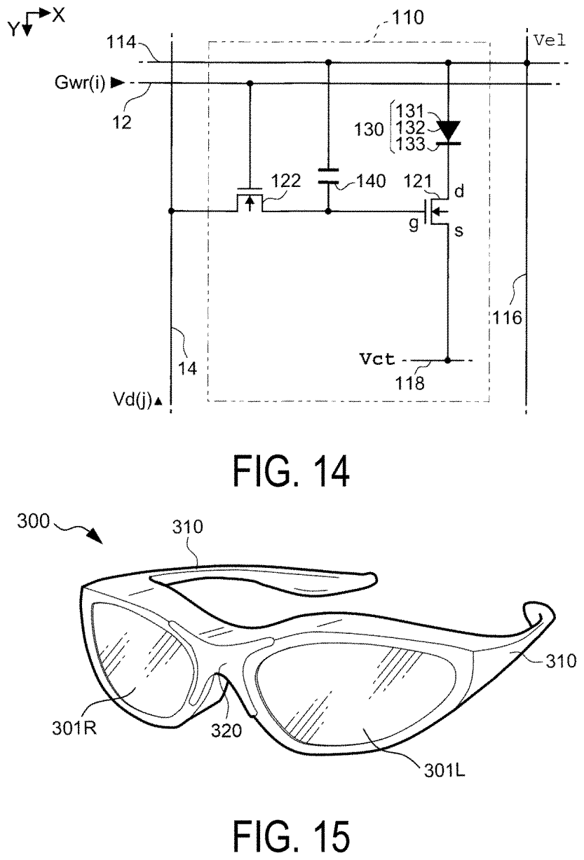

In the electro-optical device 10 according to the embodiment described above, the transistor 121, the OLED 130, and the power-supply wiring line 118 are arrayed in this order with the power-supply wiring line 116 being the reference. However, it may be possible to apply this to a configuration in which the OLED 130, the transistor 121, and the power-supply wiring line 118 are arrayed in this order, as illustrated in FIG. 14. In this configuration, the anode of the OLED 130 is the common electrode, and is coupled to the power-supply wiring line 116. In addition, the cathode of the OLED 130 is the pixel electrode, and is coupled to the power-supply wiring line 118 through the transistor 121. Thus, the configuration illustrated in FIG. 14 has a problem of the wiring line resistance of the power-supply wiring line 118 used to supply the potential Vct at the low-level power source for the OLED 130.

That is, the problem of the wiring line resistance of the power-supply wiring line used to supply the power source potential for the OLED 130 is irrelevant to whether the power source potential is at the high level or the low level, and lies in a power-supply wiring line at the side of the pixel electrode of the OLED 130, that is, a power-supply wiring line used to supply a potential that is not at the side of the common electrode.

In addition, description has been made of the OLED 130 used as one example of the light emitting element in the electro-optical device 10 according to the embodiment. However, other light emitting elements may be used. For example, an LED may be used as the light emitting element.

The embodiment is configured such that the threshold voltage of the transistor 121 of the pixel circuit 110 is not compensated. However, it may be possible to employ a configuration in which the threshold voltage is compensated. The channel type of the transistor 121, 122 is not limited to that in the embodiment or the like.

Electronic Device

Next, an electronic device to which the electro-optical device 10 according to the embodiment is applied will be described. The electro-optical device 10 is suitable for application with a small pixel and high definition display. Thus, a head-mounted display will be described as an example of the electronic device.

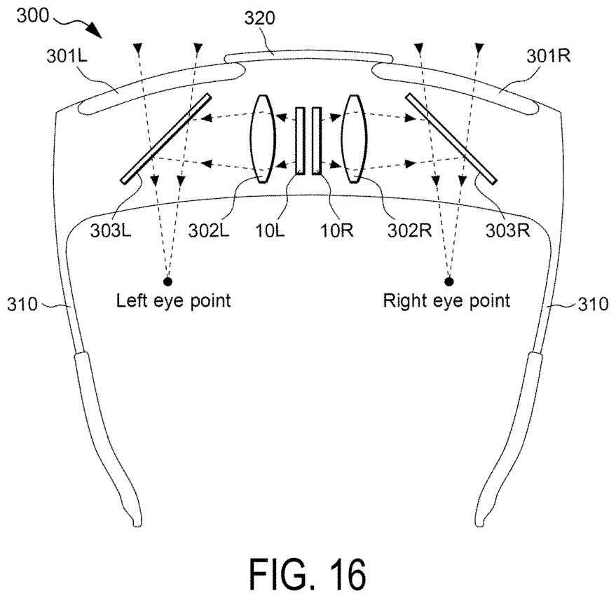

FIG. 15 is a diagram illustrating the external appearance of a head-mounted display. FIG. 16 is a diagram illustrating an optical configuration of the display.

First, as illustrated in FIG. 15, the head-mounted display 300 includes a temple 310, a bridge 320, and lenses 301L and 301R as with typical eyeglasses in terms of the external appearance. In addition, as illustrated in FIG. 16, the head-mounted display 300 includes a left-eye electro-optical device 10L and a right-eye electro-optical device 10R provided in the vicinity of the bridge 320 and at the back (at the lower side in the drawing) of the lenses 301L and 301R.

An image display surface of the electro-optical device 10L is disposed so as to be at the left in FIG. 16. With this configuration, the display image by the electro-optical device 10L exits through an optical lens 302L in the direction of nine o'clock in the drawing. A half mirror 303L reflects the display image by the electro-optical device 10L toward the direction of six o'clock while allowing light entering from the direction of 12 o'clock to pass through. An image display surface of the electro-optical device 10R is disposed so as to be at the right that is opposite to the electro-optical device 10L. With this configuration, the display image by the electro-optical device 10R exits through an optical lens 302R in the direction of three o'clock in the drawing. A half mirror 303R reflects the display image by the electro-optical device 10R toward the direction of six o'clock while allowing light entering from the direction of 12 o'clock to pass through.

With this configuration, a wearer of the head-mounted display 300 can observe the display images by the electro-optical devices 10L and 10R in a see-through state in which the display images by the electro-optical devices 10L and 10R overlap with the outside.

In addition, in this head-mounted display 300, of images for both eyes with parallax, an image for a left eye is displayed by the electro-optical device 10L, and an image for a right eye is displayed by the electro-optical device 10R. This makes it possible to cause a wearer to sense the displayed images as an image displayed having a depth or a three dimensional effect.

In addition to the head-mounted display 300, it is possible to apply an electronic device including the electro-optical device 10 to an electronic viewing finder in a video camera, a lens-exchangeable digital camera, or the like, a personal digital assistant, a display unit of an arm timepiece, a light bulb of a projection-type projector, or the like.

Notes

On the basis of the description above, it is possible to obtain preferred aspects of the present disclosure, for example, in the following manner. Note that, in the following description, in order to facilitate understanding of each aspect, the reference characters attached in the drawings are also written in blankets for the purpose of convenience. However, this does not intend to limit the present disclosure to the aspects illustrated in the drawings.

Note 1

An electro-optical device (10) according to one aspect (Note 1) of the present disclosure includes: a light emitting element (130) configured to emit light according to a current flowing between a pixel electrode (131) and a common electrode (133); a plurality of power-supply wiring lines (116) provided at a side of the pixel electrode (131) and configured to supply a power source potential (Vel); a plurality of data lines (14); a data-signal outputting circuit (50) configured to output a data signal having a potential according to a current, to one data line (14) of the plurality of data lines (14); and a conductive wiring line (271) provided so as to overlap with the data-signal outputting circuit (50) in plan view and configured to be supplied with the power source potential (Vel) through a plurality of mounting terminals (20a), in which each of the plurality of power-supply wiring lines (116) is provided between the plurality of data lines (14) in plan view and is electrically coupled to the conductive wiring line (271).

With this aspect, it is possible to reduce the resistance of the wiring line from the mounting terminal (20a) to the power-supply wiring line (116), the wiring line being supplied with the power source potential (Vel).

Note 2

In a specific example (Note 2) according to the Note 1, the plurality of data lines (14) and the plurality of power-supply wiring lines (116) are formed of a same wiring layer (260). With this aspect, the data line (14) is shielded by the power-supply wiring line (116). This makes it possible to suppress a reduction in the display quality.

Note 3

In a specific example (Note 3) according to the Note 1 or Note 2, each of the plurality of power-supply wiring lines (116) is electrically coupled to the conductive wiring line (271) through a contact hole (Ct11 to Ct14). With this aspect, it is possible to couple the conductive wiring line (271) and the plurality of power-supply wiring lines (116).

Note 4

In a specific example (Note 4) according to any one of Note 1 to Note 3, in a portion of the conductive wiring line (271) that overlaps with the data-signal outputting circuit (50) in plan view, a width (W2) in a direction intersecting a direction in which the plurality of data lines (14) extend is equal to or more than a width (W1) of a display region including the light emitting element. With this aspect, the conductive wiring line 271 having a large width achieves a reduced resistance.

Note 5

In a specific example (Note 5) according to any one of Note 1 to Note 4, the conductive wiring line (271) is provided at a layer above the plurality of data lines (14). With this aspect, the data line (14) is covered with the conductive wiring line (271) and is shielded. This makes it possible to suppress a reduction in the display quality. Note that the “conductive wiring line (271) is provided at a layer above the data line (14)” specifically means that the conductive wiring line (271) is formed after the data line 14 is formed, and also means a positional relationship when components of the semiconductor substrate are at the lowermost layer in cross-sectional view.

Note 6

An electronic device according to a specific example (Note 6) of any one of Note 1 to Note 5 includes the electro-optical device.

What is claimed is:

1. An electro-optical device, comprising:
a light emitting element configured to emit light according to a current flowing between a pixel electrode and a common electrode;
a plurality of power-supply wiring lines provided at a side of the pixel electrode and including a power-supply wiring line to which a power source potential is supplied;
a plurality of data lines provided along a predetermined direction;
a data-signal outputting circuit configured to output a data signal to one data line of the plurality of data lines; and
a conductive wiring line provided so as to overlap with the data-signal outputting circuit in plan view and configured to be supplied with the power source potential through a plurality of mounting terminals, wherein
each of the plurality of power-supply wiring lines is provided between the plurality of data lines in plan view and is electrically coupled to the conductive wiring line.

2. The electro-optical device according to claim 1, wherein
the plurality of data lines and the plurality of power-supply wiring lines are formed of a same wiring layer.

3. The electro-optical device according to claim 1, wherein
each of the plurality of power-supply wiring lines is electrically coupled to the conductive wiring line through a contact hole.

4. The electro-optical device according to claim 1, wherein
in a portion of the conductive wiring line that overlaps with the data-signal outputting circuit in plan view, a width in a direction intersecting a direction in which the plurality of data lines extend is equal to or more than a width of a display region including the light emitting element.

5. The electro-optical device according to claim 1, wherein
the conductive wiring line is provided at a layer above the plurality of data lines.

6. An electronic device comprising the electro-optical device according to claim 1.
